(19) United States
(12) Patent Application Publication
(10) Pub. No.: US 2011/0116861 A1
(43) Pub. Date: May 19, 2011

(54) BATTERY PACK LOCKING DEVICE

(76) Inventors: Zhi Zhang, (US); Jiang Li, (US); Lingling Zou, (US)

(21) Appl. No.: 12/950,003

(22) Filed: Nov. 19, 2010

(30) Foreign Application Priority Data
Nov. 19, 2009 (CN) 200920255202.5

(51) Int. Cl. H05K 5/02

(52) U.S. Cl. 403/322.1

(57) ABSTRACT

The present application provides a battery pack locking device, comprising a button, a snap element for engaging the battery pack with an electrical appliance, a linkage controlled by the button, a spring provided below the button and a support. The snap element is hinged to the support at one end and the first end of the linkage is disposed below the button. When the button is pressed down, the first end moves down and the second end of the linkage moves upwardly relative to the first end. Also, the snap connecting portion moves downwardly in a curved path without squeezing the snap groove of the electrical appliance, resulting in decreased friction between the parts and a reduced force necessary to press down the button. Accordingly, the battery pack can be easily mounted to and removed from an electrical appliance.

### CROSS-REFERENCE TO RELATED APPLICATIONS

This application claims priority under 35 U.S.C. § 119 to CN 200920255202.5 filed Nov. 19, 2009, which may be hereby incorporated by reference.

### FEDERALLY SPONSORED RESEARCH OR DEVELOPMENT

Not Applicable.

### TECHNICAL FIELD

The present application relates to a coupling structure between a battery pack and a body of an electric tool, more particularly to a battery pack locking device.

### BACKGROUND OF THE INVENTION

Prior art rechargeable electric tools generally comprise a body and a battery pack removeably connected to the body to facilitate re-charging and replacement. The battery pack and the body are positioned in an up-and-down relation via a horizontal rib groove structure and in a front-and-rear relation through cooperation between a snap element on the battery pack and a slot in the body. A return spring may be provided below a button and the snap connecting portion of the snap element may pass through a snap opening provided in the upper surface of a battery pack case to allow for engagement with the body. However, in the previous battery pack lock coupling structure, the snap element and button are integrally formed wherein the front end surface of the snap element may be a vertical surface perpendicular to the body of the snap element. As a result, when the button is pressed down, it causes the snap element to move downwardly along the snap opening on the battery pack case. During this process, because the snap element corresponds to a cantilevered end of a lever, there may be a rotation trend which may result in some friction between the snap connecting portion of the snap element and the snap opening on the battery pack case as well as insensitiveness of the button.

### SUMMARY OF THE INVENTION

In view of the above shortcomings related to the prior art, the present application is directed to a battery pack locking device which is highly reliable and avoids the squeeze and friction phenomenon between the snap element and the battery pack case while improving the sensitivity of the button.

Specifically, the present application may include a battery pack locking device having a button, a snap element, a linkage controlled by the button and an elastic element below the button. The button may be mounted on a case of the battery pack and the snap element may be coupled to the case at one end and, at the other end, the case may have a snap connecting portion exposed out of the case. The snap element may have an engaging portion through which it engages with the linkage.

Further, the engaging portion of the snap element may have a side arm at an angle with respect to the body of the snap element. And the linkage may have a side arm at an angle with respect to the linkage body, where the side arm and the engaging portion of the snap element overlap.

Also, the linkage may have a first end cooperating with a lower end surface of the button and a second end cooperating with the case of the battery pack. The first end of the linkage may be in contact with the lower end surface of the button and the second end of the linkage may be rotatably coupled to the case. In addition, the second end of the linkage may move laterally along the case. The first end of the linkage may be rotatably coupled to the lower end of the button. The first end of the linkage may move longitudinally along the case. And the battery pack locking device may further comprise a spring provided below the snap element. And a rear end surface of the snap connecting portion may be a ramped surface.

By using the linkage-driving-snap element mechanism to bring the snap connecting portion of the snap element to rotate in an opposite direction, it may be unnecessary to use the battery pack case for guidance, thereby the squeeze and friction between the battery pack case and the snap element may be decreased.

### BRIEF DESCRIPTION OF THE DRAWINGS

This invention will be further described in details in combination of the following accompanying drawings and embodiments.

FIG. 1 is a perspective view of the outside of a battery pack with a battery pack locking device according to the present application;

FIG. 2 is a perspective view of a battery pack locking device according to one embodiment of the present application;

FIG. 3 is a side view of the battery pack locking device according to one embodiment of the present application shown in FIG. 2;

FIG. 4 is a top view of the battery pack locking device according to one embodiment of the present application shown in FIG. 2;

FIG. 5 is a cross-sectional view of the battery pack locking device according to one embodiment of the present application taken along the line A-A shown in FIG. 4.

### DETAILED DESCRIPTION

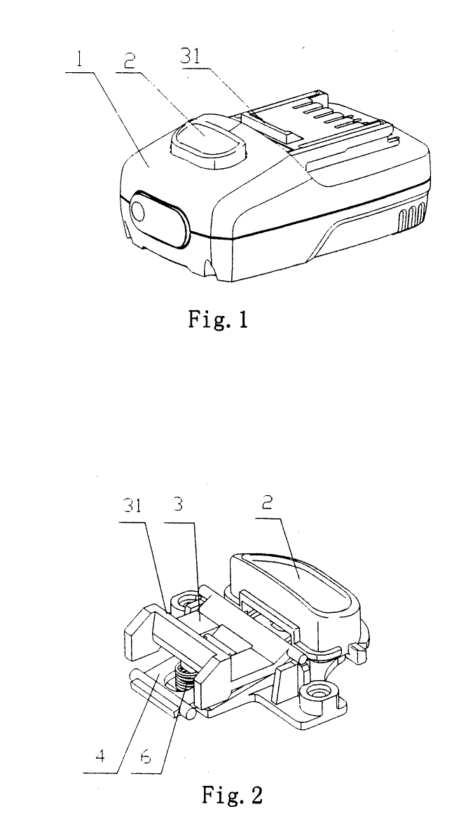

Embodiments of the present application will be described below in greater detail with reference to the accompanying drawings. As shown in FIG. 1, there is a diagram of the outside of a battery pack with a battery pack locking device according to the present application. The battery pack may include a case 1 formed by joining an upper cover and a lower cover together and having a battery pack locking device disposed thereon. Wherein a button 2 and a snap connecting portion 31 of a snap element of the locking device are exposed out of a surface of the case 1. The rear end surface of the snap connecting portion 31 may be a ramped surface such that the snap connecting portion 31 may be pressed down smoothly by an electrical appliance being pushed in laterally.

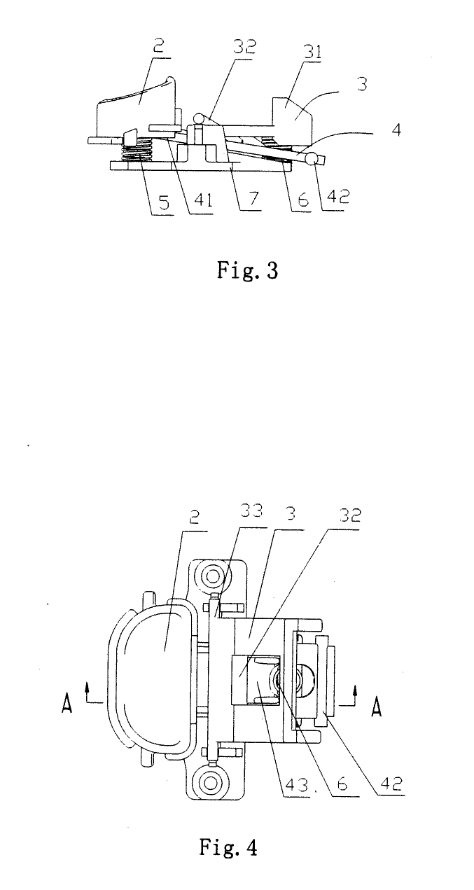

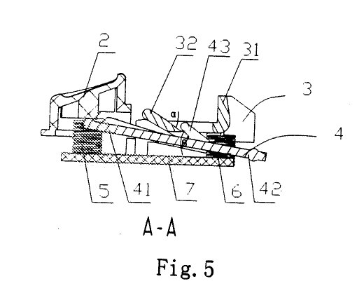

FIGS. 2 to 5 illustrate a battery pack locking device of the present application comprising a button 2, an elastic element 5, a snap element 3, a linkage 4 and a spring 6 for enhancing the reset capability of the snap element 3. The snap element 3 may be provided with an engaging portion 32 coupled to the linkage 4. The engaging portion 32 may be a side arm at an angle α with respect to the body of the snap element 3 and the linkage 4 may be provided with a side arm 43 at an angle β with respect to the body of the linkage. A support 7 may be provided in the case 1 and button 2 may be provided above the support 7. Two ends of the spring 5 abut the support 7 and the bottom end of button 2, respectively. The snap element 3 has a snap connecting portion 31 at one end and a fixed end 33 coupled to the case 1 at the other end. When inserting the battery pack into the base of an electrical appliance along the sliding grooves at both sides of the upper cover of the battery pack, the snap connecting portion 31 of the snap element 3 will be pressed downwardly to a plane position on the electrical appliance in contact with the snap element until the snap connecting portion 31 is below the snap groove of the electrical appliance. As a result, the snap element 3 bounces up through its own elastic force or reset function of the spring 6 and the snap connecting portion 31 snaps into the snap groove of the electrical appliance. At this time, the electrical appliance and the battery pack are now securely assembled. When pulling the electrical appliance away from the battery pack along the sliding groove, a vertical surface of the snap connecting portion 31 may abut against a vertical surface of the snap groove of the electrical appliance, which prevents the battery pack from coming apart from the electrical appliance.

The battery pack may be disconnected from the electrical appliance in multiple different ways, according to the following embodiments. In a first embodiment, the linkage 4 may be disposed blow the snap element 3. A first end 41 of the linkage 4 may be in contact with a lower end surface of the button 2, and a second end 42 of the linkage 4 may be hinged on the case 1 or a part fixed to case 1. The snap element 3 may be hinged on case 1 at a fixed end 33 which may be adjacent to the button 2 and has a snap connecting portion 31 at the other end. A side arm 43 of the linkage and a side arm of the snap element 3 will then overlap each other. Specifically, a lower arm surface of the linkage side arm 43 overlaps an upper arm surface of the side arm of the snap element 3. When the button 2 is pressed down, it will move down and cause the first end 41 of the linkage 4 in contact with the button 2 to move down. As a result, the linkage 4 may swing downwardly around its own second end 42 (the fixed end), and the side arm 43 of the linkage will also rotate around the second end 42 of the linkage 4 creating a downward movement in the vertical direction. As such, the side arm of the snap element 3 will be pressed downward. Since the snap element 3 may be fixed at one end, it will rotate around the fixed end 33 downwardly and cause its snap connecting portion 31 to move downwardly in a curved path. The battery pack cannot be separated from the electrical appliance until the snap connecting portion 31 releases from the snap groove of the electrical appliance and the electrical appliance may be pulled out along the sliding groove.

In a second embodiment, the linkage 4 may be disposed below the snap element 3. The linkage 4 may be hinged on the button 2 at the first end 41 and have a projecting portion (not shown) that may be slidable laterally within a lateral sliding groove of the case 1 or parts fixed to the case 1 at the second end 42. Alternatively, the second end 42 may be provided with a recess (not shown) adapted to slide laterally on a projecting portion of the case 1 or parts fixed to the case 1. The snap element 3 may be hinged on the case 1 at the fixed end 33 that may be adjacent to the button 2 and have, at the other end, a snap connecting portion 31 having the same functions as that of the first embodiment. Side arm 43 of the linkage and side arm of the snap element 3 overlap each other. Specifically, the lower arm surface of the linkage side arm 43 overlaps the upper arm surface of the side arm of snap element 3. When the button 2 is pressed down, it will move down and cause the end (the first end 41) of the linkage 4 hinged on the button 2 to move down. At the same time, the linkage 4 may rotate and its other end (the second end 42) may just move laterally. As a result, the side arm 43 of the linkage will also rotate and press the side arm of the snap element 3 downward. Since the snap element 3 may be fixed at one end, it will rotate around the fixed end 33 downwardly and cause its snap connecting portion 31 to move down in a curved path. The battery pack will not be separated from the electrical appliance until the snap connecting portion 31 releases from the snap groove of the electrical appliance and the electrical appliance may then be pulled out along the sliding groove.

In another embodiment, the linkage 4 may be disposed below the snap element 3. The linkage 4 may have a first end 41 that may be in contact with the button 2 and provided with a projecting portion (not shown) adapted to slide longitudinally within a longitudinal sliding groove of the case 1 or parts fixed to the case 1. The second end 42 may be provided with a projecting portion (not shown) adapted to slide laterally within a lateral sliding groove of the case 1 or parts fixed to the case 1. The snap element 3 may be hinged on the case 1 at the fixed end 33 and has, at the other end, a snap connecting portion 31 having the same functions as that of the first embodiment. Side arm 43 of the linkage and side arm of the snap element 3 overlap each other. Specifically, the lower arm surface of the linkage side arm 43 overlaps the upper arm surface of the side arm of snap element 3. When the button 2 is pressed down, it will move down and cause the end of the linkage 4 in contact with the button 2 to move down. At the same time, the linkage 4 may rotate and its other end may move laterally. As a result, the side arm 43 of the linkage will also rotate and press the side arm of the snap element 3 downward. Since the snap element 3 may be fixed at one end, it will rotate around the fixed end 33 downwardly and cause its snap connecting portion 31 to move down in a curved path.

In another embodiment, the linkage 4 may be disposed above the snap element 3. The linkage 4 may be provided with a side arm 43 at an angle β with respect to the body of the linkage, and the snap element 3 may be provided with an engaging portion 32 in a form of side arm at an angle α with respect to the body of the snap element. A side arm 43 of the linkage and a side arm of the snap element 3 overlap each other. Specifically, the lower arm surface of the linkage side arm 43 overlaps the upper arm surface of the side arm of snap element 3. When the button 2 is pressed down, it will move down, causing the first end 41 of the linkage 4 to move down and the whole linkage 4 and its side arm 43 to rotate. At the same time, the side arm 43 of the linkage 4 may move in a longitudinal direction and press the side arm of the snap element 3 downwardly. Since the snap element 3 may be fixed at one end, it will rotate around the fixed end 33 downwardly and cause its snap connecting portion 31 to move down in a curved path.

In the above embodiments, the snap element may be rotated through the rotation of the linkage through a coupling of the two elements. Specifically, it may be achieved by providing the snap element and the linkage with a side arm at an angle with respect to their respective body in an overlapped manner. The snap element 3 of the present application, at the end adjacent to the button 2, may also be fixedly coupled to the case 1 or a part fixed to the case 1. In such a case, the snap element 3 may self-reset without a second spring disposed therebelow as long as it has enough elastic force.

The above mentioned embodiments are only explanatory for the concept and principle of this invention, without limitation to the contents of the invention. Those skilled in the art will contemplate that this invention will have many other modifications or substitutes which are still falling within the scope of this invention.

What is claimed is:

1. A battery pack locking device, comprising:
a button;
a snap element;
a linkage controlled by the button; and,
an elastic element provided below the button, wherein the button may be mounted on a case of a battery pack, and wherein the snap element may be coupled to a first end of the case and a snap connecting portion may be provided at a second end of the case,
the snap element may be provided with an engaging portion to allow for coupling with the linkage.

2. The battery pack locking device according to claim 1, wherein the engaging portion of the snap element may be a side arm having an angle with respect to the body of the snap element.

3. The battery pack locking device according to claim 1, wherein the linkage has a side arm having an angle with respect to the linkage body, and further wherein the side arm and the engaging portion of the snap element overlap.

4. The battery pack locking device according to claim 1, wherein the linkage has a first end cooperating with a lower end surface of the button and a second end cooperating with the case of the battery pack.

5. The battery pack locking device according to claim 4, wherein the first end of the linkage is in contact with the lower end surface of the button and the second end of the linkage is rotatably coupled to the case.

6. The battery pack locking device according to claim 4, wherein the second end of the linkage moves laterally along the case.

7. The battery pack locking device according to claim 6, wherein the first end of the linkage is rotatably coupled to the lower end of the button.

8. The battery pack locking device according to claim 6, wherein the first end of the linkage moves longitudinally along the case.

9. The battery pack locking device according to claim 1, wherein the battery pack further comprises a spring provided below the snap element.

10. The battery pack lock device according to claim 1, wherein a rear end surface of the snap connecting portion is a ramped surface.
